(19) United States
(12) Patent Application Publication
(10) Pub. No.: US 2008/0142869 A1
(43) Pub. Date: Jun. 19, 2008

(54) Non-volatile memory device and method of forming the same

(75) Inventors: Kong-Sam Jang, Yongin-si (KR); Jeong-uk Han, Suwon-si (KR); Yong-tae Kim, Yongin-si (KR); Weon-ho Park, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/987,294

(22) Filed: Nov. 29, 2007

(30) Foreign Application Priority Data
Nov. 29, 2006 (KR) 10-2006-119193

(51) Int. Cl. H01L 29/788; H01L 21/336

(52) U.S. Cl. 257/315; 438/264; 257/E21.409; 257/E29.3

(57) ABSTRACT

Example embodiments relate to a non-volatile memory device and a method of forming the same. A non-volatile memory device according to example embodiments may include a conductive pattern provided on the semiconductor substrate. A tunnel insulator may be provided on the conductive pattern. A memory gate structure may be provided on the semiconductor substrate so as to cover a first end of the conductive pattern. The first end may include an upward tapering, first protrusion. A select gate structure may be provided on the semiconductor substrate so as to cover the second end of the conductive pattern. The second end may include an upward tapering, second protrusion. The coverage of the first protrusion by the memory gate structure may be greater than the coverage of the second protrusion by the select gate structure.

### PRIORITY STATEMENT

This U.S. non-provisional patent application claims priority under 35 U.S.C § 119 to Korean Patent Application 10-2006-119193, filed on Nov. 29, 2006 in the Korean Intellectual Property Office (KIPO), the entire contents of which are incorporated herein by reference.

### BACKGROUND

Example embodiments relate to semiconductor devices (e.g., non-volatile memory devices) and methods of forming the same. Non-volatile memory devices may retain their stored data even after power interruptions. Non-volatile memory devices may include mask ROMs, EPROMs, EEPROMs, and flash memory devices. EEPROMs may include a floating gate tunnel oxide type (FLOTOX-type) EEPROM, wherein two transistors may constitute one cell.

FIG. 1 is a top plan view illustrating a conventional non-volatile memory device, and FIG. 2 is a cross-sectional view taken along a line I-I′ of FIG. 1. Referring to FIGS. 1 and 2, a device isolation layer 15 may be disposed in a semiconductor substrate 10 to define an active region. A gate insulator 20 may be provided on the semiconductor substrate 10. The gate insulator 20 may include silicon oxide. A memory gate structure MG and a select gate structure SG may be provided on the gate insulator 20. The memory gate structure MG may include the gate insulator 20, a floating gate 32a, a first intergate dielectric 34a, and a sensing gate 36a. The gate insulator 20 between the floating gate 32a and the semiconductor substrate 10 may have an opening. A cylindrical tunnel insulator 25 may be provided in the opening and may be thinner than the gate insulator 20. The select gate structure SG may include the gate insulator 20, a first select gate 32b, a second intergate dielectric 34b, and a second select gate 36b. A floating junction region 14 may be provided in the semiconductor substrate 10 between the memory gate structure MG and the select gate structure SG. A source region 12 may be provided in the semiconductor substrate 10 adjacent to the memory gate structure MG, and a drain region 16 may be provided in the semiconductor substrate 10 adjacent to the select gate structure SG.

A programming or erasing operation of the conventional non-volatile memory device may be conducted by applying a higher voltage to the drain region 16 or the sensing gate 36a, which may lead to an increase in the space between the floating junction region 14 and the drain region 16 as well as the space between the floating junction region 14 and the source region 12. In addition, the space between the floating junction region 14 and the source region 12 must be sufficiently long so as to reduce or prevent the occurrence of a punchthrough therebetween. Therefore, it may be more difficult to decrease the cell size of a conventional non-volatile memory device. Furthermore, the uniformity of the tunnel insulator 25 may not be sufficient to reduce cell distribution.

### SUMMARY

Example embodiments are directed to non-volatile memory devices. A non-volatile memory device according to example embodiments may include a conductive pattern on a semiconductor substrate; a tunnel insulator on the conductive pattern; a memory gate structure covering a first end of the conductive pattern; and/or a select gate structure covering a second end of the conductive pattern. A first protrusion may be provided at the first end of the conductive pattern, and a second protrusion may be provided at the second end of the conductive pattern. The coverage of the first protrusion by the memory gate structure may be greater than the coverage of the second protrusion by the select gate structure.

Example embodiments are also directed to methods of forming a non-volatile memory device. A method according to example embodiments may include forming a conductive pattern on a semiconductor substrate, the conductive pattern having a first end and a second end, a base portion between the first and second ends, a first protrusion at the first end, and a second protrusion at the second end; forming a tunnel insulator on the conductive pattern; forming a memory gate structure on the first protrusion; and/or forming a select gate structure on the second protrusion.

### BRIEF DESCRIPTION OF THE DRAWINGS

FIG. 1 is a top plan view illustrating a conventional non-volatile memory device.

FIG. 2 is a cross-sectional view of the conventional non-volatile memory device of FIG. 1, taken along a line I-I′.

FIG. 3 is a top plan view illustrating a non-volatile memory device according to example embodiments.

FIG. 4 is a cross-sectional view of the non-volatile memory device according to example embodiments of FIG. 3, taken along a line II-II′.

FIGS. 5A through 5G are cross-sectional views illustrating a method of forming a non-volatile memory device according to example embodiments.

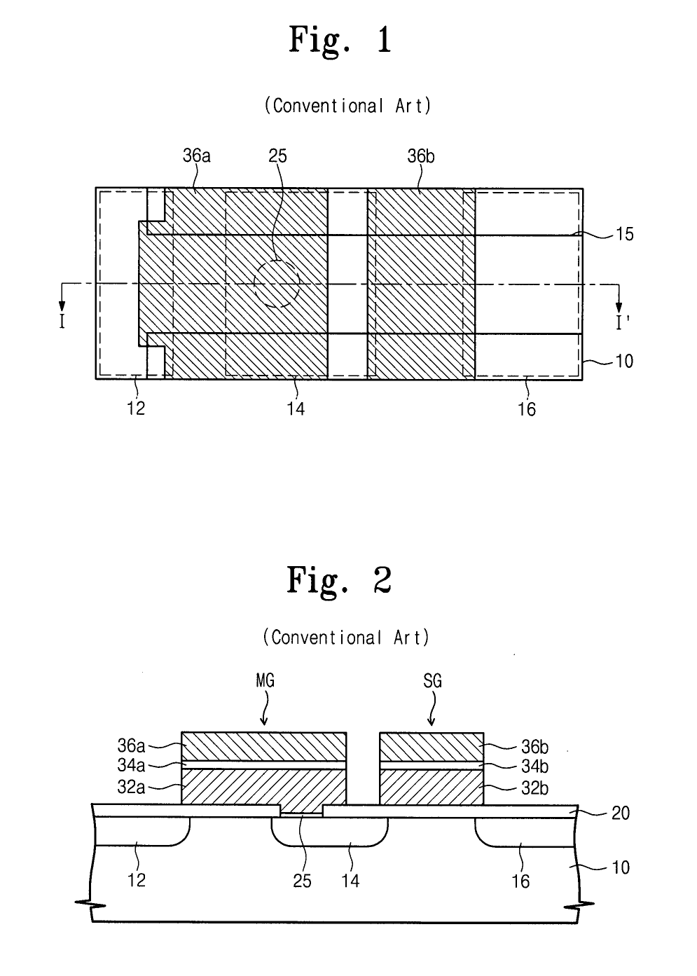

### DETAILED DESCRIPTION OF EXAMPLE EMBODIMENTS

Example embodiments will now be described with reference to the accompanying drawings. Example embodiments, however, may be embodied in many different forms and should not be construed as limited to the examples set forth herein. Rather, example embodiments have been provided to help convey the scope of the disclosure to those of ordinary skill in the art. In the drawings, the thicknesses of layers and regions may have been exaggerated for clarity.

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

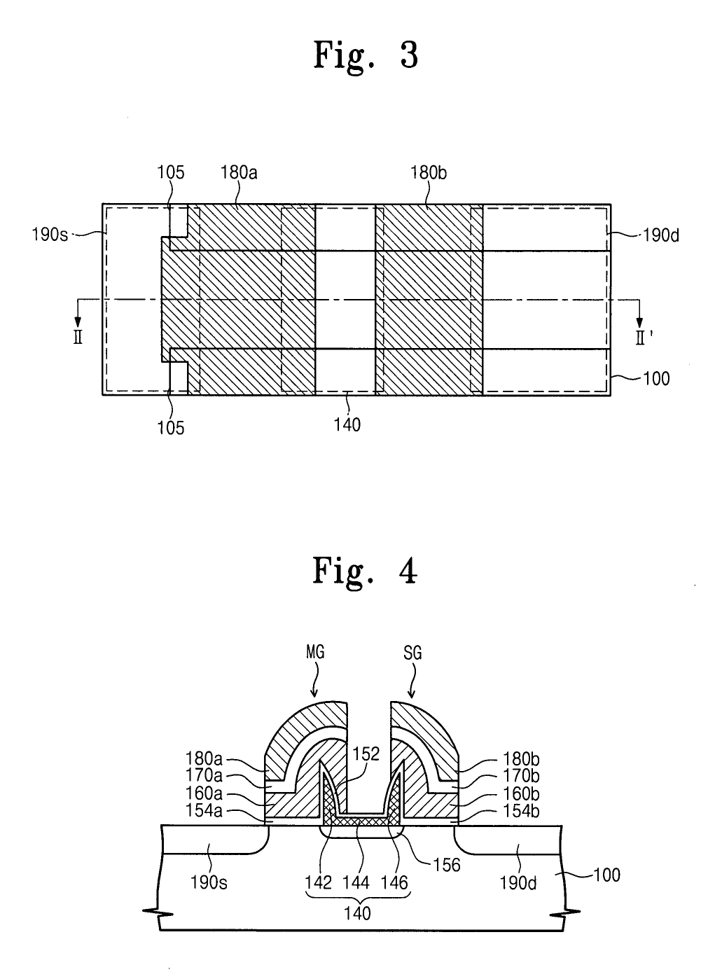

FIG. 3 is a top plan view illustrating a non-volatile memory device according to example embodiments, and FIG. 4 is a cross-sectional view taken along a line II-II′ of FIG. 3. Referring to FIGS. 3 and 4, a device isolation layer 105 may be disposed in a semiconductor substrate 100 to define an active region. A conductive pattern 140 may be provided on the semiconductor substrate 100. The conductive pattern 140 may include a polysilicon doped with impurities. The conductive pattern 140 may include a base portion 144 in contact with the semiconductor substrate 100, a first protrusion 142 at one end (e.g., first end) of the base portion 144, and a second protrusion 146 at the other end (e.g., second end) of the base portion 144. The first and second protrusions 142 and 146 may taper upwards. The second protrusion 146 may be substantially symmetrical to the first protrusion 142 about a central axis of the base portion 144. Each of the first and second protrusions 142 and 146 may have an outer side surface that is substantially perpendicular to a bottom surface of the base portion 144 and an inner side surface that is convex. An acute angle may be formed at the convergence of the outer and inner side surfaces.

A tunnel insulator 152 may be provided on the conductive pattern 140. The tunnel insulator 152 may include silicon oxide. The tunnel insulator 152 may be made of at least one material selected from the group consisting of thermal oxide and middle-temperature oxide. For example, where the tunnel insulator 152 is made of the combination of thermal oxide and middle-temperature oxide, the thermal oxide may be provided on the conductive pattern 140, and the middle-temperature oxide may be provided on the thermal oxide.

A memory gate structure MG may be provided on the semiconductor substrate 100 so as to cover one end of the conductive pattern 140. The memory gate structure MG may include a first gate insulator 154a, a floating gate 160a, a first intergate dielectric 170a, and a sensing gate 180a. The floating gate 160a may cover the first protrusion 142. A select gate structure SG may be provided on the semiconductor substrate 100 so as to cover the other end of the conductive pattern 140. The select gate structure SG may include a second gate insulator 154b, a first select gate 160b, a second intergate dielectric 170b, and a second select gate 180b.

Each of the first and second gate insulators 154a and 154b may be made of at least one material selected from the group consisting of thermal oxide and middle-temperature oxide. The tunnel insulator 152 may be thinner than the first gate insulator 154a and the second gate insulator 154b. The floating gate 160a, the sensing gate 180a, the first select gate 160b, and the second select gate 180b may include polysilicon. The first intergate dielectric 170a and the second intergate dielectric 170b may include oxide-nitride-oxide (ONO). The memory gate structure MG may cover the first protrusion 142 to a greater extent than the select gate structure SG covers the second protrusion 146, thus assuring a sufficient alignment margin between the first protrusion 142 and the memory gate structure MG.

A floating impurity region 156 may be provided in the semiconductor substrate 100 so as to be in contact with the conductive pattern 140. The floating impurity region 156 may also include the impurities of the conductive pattern 140. A source region 190s may be provided in the semiconductor substrate 100 adjacent to the memory gate structure MG, and a drain region 190d may be provided in the semiconductor substrate 100 adjacent to the select gate structure SG. In the non-volatile memory device according to example embodiments, the first protrusion 142 may be tip-shaped. Thus, unlike the conventional memory device of FIG. 2, a tunnel insulator may not be in contact with a semiconductor substrate and a floating junction region, thus making cell shrinkage possible.

A programming operation may include applying a program voltage (e.g., about 9-10 volts) to the sensing gate 180a, applying a pass voltage (e.g., about 9-10 volts) to the second select gate 180b, and applying a ground voltage to the drain region 190d. Consequently, charges may migrate to the conductive pattern 140 from the drain region 190d through the floating impurity region 156. Accordingly, an electric field may be concentrated at the first protrusion 142 so as to store the charges in the floating gate 160a from the first protrusion 142 through the tunnel insulator 152.

An erasing operation may include applying an erase voltage (ground voltage) to the sensing gate 180a, applying a pass voltage (e.g., about 9-10 volts) to the second select gate 180b, and applying a voltage of about 9-10 volts to the drain region 190d. Consequently, the charges stored in the floating gate 160a may be ejected through the tunnel insulator 152 to the first protrusion 142 where the electric field is concentrated.

A read operation may include applying a power supply voltage V_{cc} (e.g., about 1-2 volts) to the sensing gate 180a and the second select gate 180b, applying a voltage (about 0.4-1 volt) lower than the power supply voltage to the drain region 190d, and applying a ground voltage to the source region 190s to detect current induced to the drain region 190d and the source region 190s.

Because programming and erasing operations may be conducted using a tip-shaped, first protrusion 142, the space between the source region 190s and the floating impurity region 156 may be reduced. In addition, because an electric field may be concentrated at the first protrusion 142, programming and erasing efficiency may be enhanced, and operation voltage may drop.

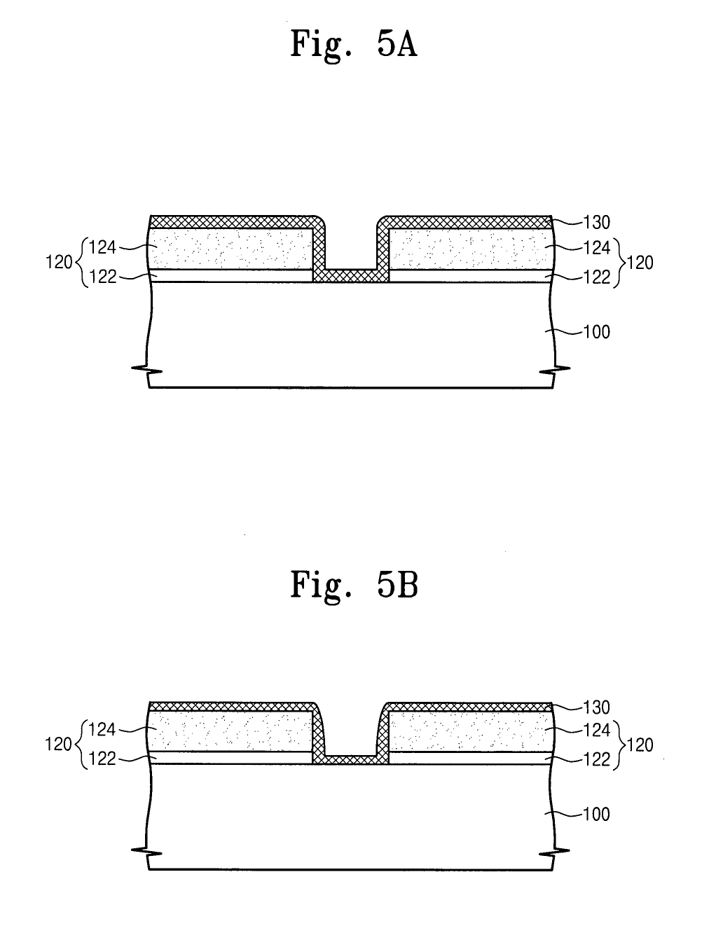

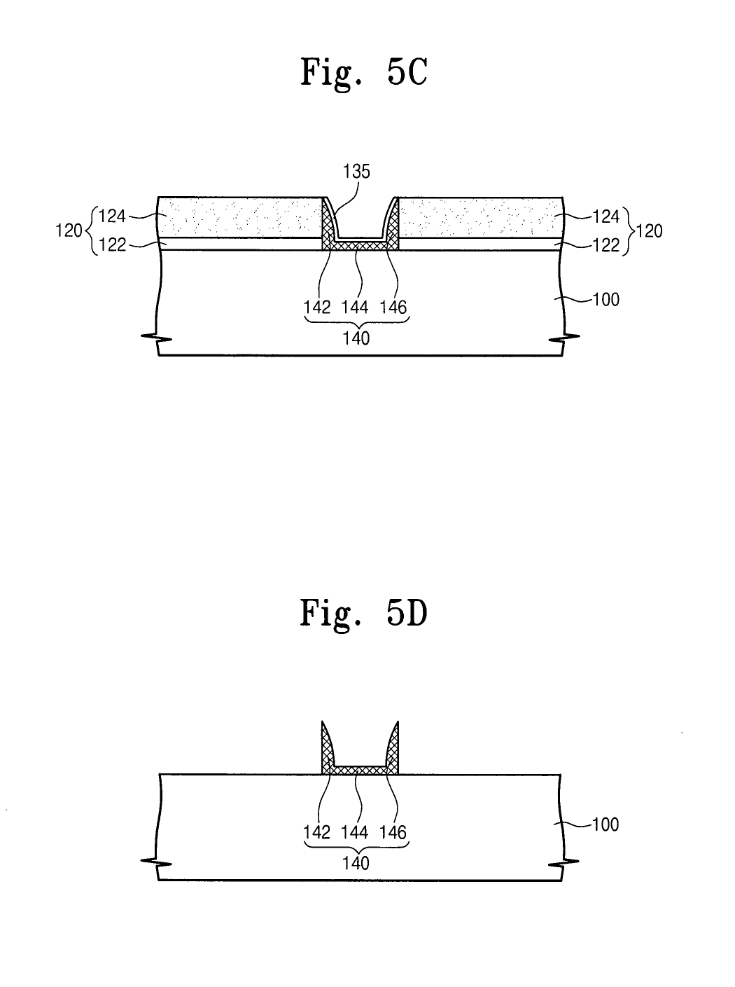

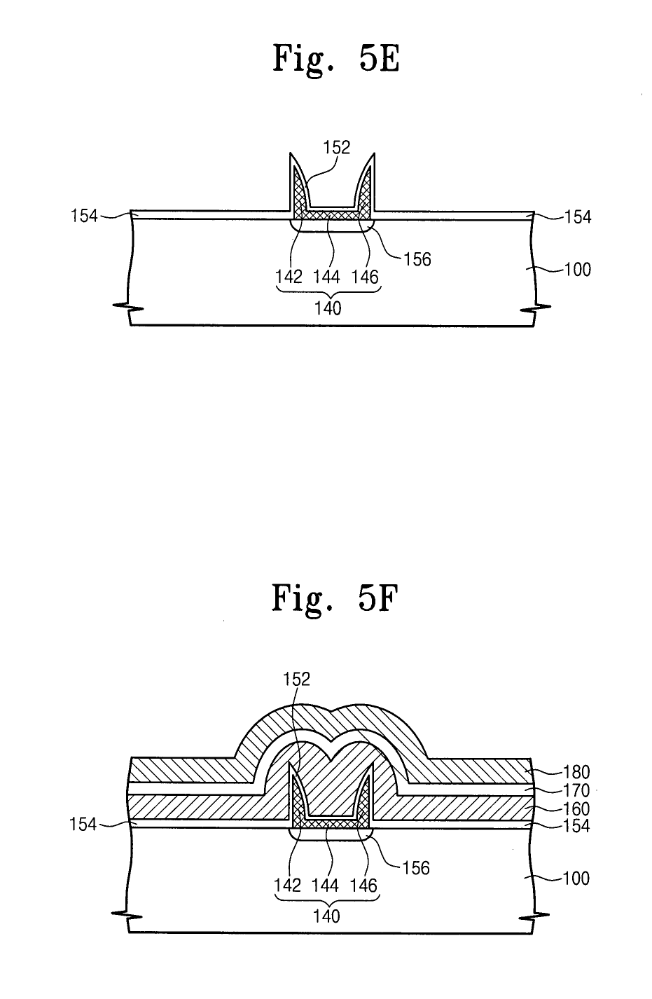

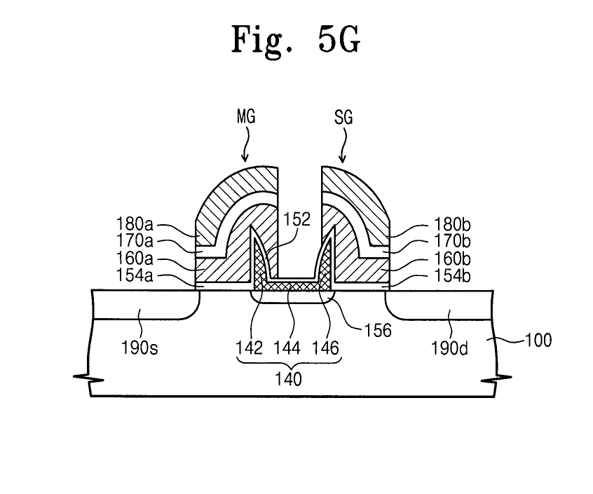

FIGS. 5A through 5G are cross-sectional views illustrating a method of forming a non-volatile memory device according to example embodiments. Referring to FIG. 5A, a pad oxide layer may be formed on a semiconductor substrate 100. The pad oxide layer may include silicon oxide and may be formed by a thermal oxidation process or a chemical vapor deposition (CVD) process. A hard mask layer may be formed on the pad oxide layer. The hard mask layer may include silicon oxynitride and may be formed by a CVD process. A photoresist pattern (not shown) may be formed on the hard mask layer. Using the photoresist pattern as a mask, an etch process may be performed to form a mask pattern 120 including a hard mask pattern 124 and a pad oxide pattern 122. The mask pattern 120 may include an opening formed to expose the semiconductor substrate 100. A conductive layer 130 may be formed to cover the mask pattern 120 such that at least a portion of the opening is filled. The conductive layer 130 may be formed of a polysilicon doped with impurities.

Referring to FIGS. 5B through 5D, a conductive pattern 140 may be formed in the opening. The conductive pattern 140 may include a base portion 144 that is in contact with the semiconductor substrate 100, a first protrusion 142 formed at one end of the base portion 144, and a second protrusion 146 formed at the other end of the base portion 144. Each of the first and second protrusions 142 and 146 may have an outer side surface that is substantially perpendicular to a bottom surface of the base portion 144 and an inner side surface that extends from the top surface of the base portion 144 to converge with the outer side surface. Thus, an acute angle may be formed at the convergence of the side surfaces. The inner side surface may be convex. The base portion 144 may be formed to a thickness of about 1,000 angstroms.

Referring to FIG. 5B, the formation of the conductive pattern 140 may include anisotropically etching the conductive layer 130 so as to partially remove the conductive layer 130. Referring to FIG. 5C, the conductive layer 130 may be planarized so as to remove the portion of the conductive layer 130 on the upper surface of the mask pattern 120, thus forming the conductive pattern 140 in the opening. The conductive pattern 140 may be thermally oxidized to form a silicon oxide layer 135 on the conductive pattern 140. The silicon oxide layer 135 may form an acute angle at the point of convergence of the inner and outer side surfaces. The silicon oxide layer 135 may be formed at a temperature of about 800 degrees C.

Referring to FIG. 5D, the mask pattern 120 may be removed. The removal of the mask pattern 120 may include simultaneously removing the silicon oxide layer 135 and the pad oxide pattern 122 after removing the hard mask pattern 124. Referring to FIG. 5E, a tunnel insulator 152 and a gate insulator 154 may be formed on the conductive pattern 140 and the semiconductor substrate 100, respectively. The formation of the gate insulator 154 and the tunnel insulator 152 may include forming a middle-temperature oxide (MTO) by a chemical vapor deposition (CVD) process. The formation of the gate insulator 154 and the tunnel insulator 152 may also include thermally oxidizing the conductive pattern 140 and the semiconductor substrate 100. Additionally, the formation of the gate insulator 154 and the tunnel insulator 152 may include thermally oxidizing the conductive pattern 140 and the semiconductor substrate 100 to form a thermal oxide layer and forming a middle-temperature oxide to cover the thermal oxide layer. A floating impurity region 156 may be formed in the semiconductor substrate 100 that is in contact with the conductive pattern 140. The formation of the floating impurity region 156 may be performed by a thermal oxidation process or a higher-temperature process so as to diffuse the impurities from the conductive pattern 140 into the semiconductor substrate 100. Thus, the tunnel insulator 152, the gate insulator 154, and the floating impurity region 156 may be formed at the same time.

Referring to FIG. 5F, a first gate layer 160 may be formed to cover the gate insulator 154 and the tunnel insulator 152. An intergate dielectric 170 may be formed on the first gate layer 160. The intergate dielectric 170 may include an oxide-nitride-oxide (ONO) formed by a chemical vapor deposition (CVD) process. A second gate layer 180 may be formed on the intergate dielectric 170. The first gate layer 160 and the second gate layer 180 may include a polysilicon formed by a CVD process. Referring to FIG. 5G, the second gate layer 180, the intergate dielectric 170, the first gate layer 160, and the gate insulator 154 may be etched to expose at least a part of the base portion 144, thus forming a memory gate structure MG and a select gate structure SG. The memory gate structure MG may include a first gate insulator 154a, a floating gate 160a, a first intergate dielectric 170a, and a sensing gate 180a. The select gate structure SG may include a second gate insulator 154b, a first select gate 160b, a second intergate dielectric 170b, and a second select gate 180b. The memory gate structure MG may cover the first protrusion 142, and the select gate structure SG may cover the second protrusion 146.

The memory gate structure MG and the select gate structure SG may be formed at the same time and formed such that the first protrusion 142 may be more covered than the second protrusion 146 so as to sufficiently assure an alignment margin between the first protrusion 142 and the memory gate structure MG. A source region 190s may be formed in the semiconductor substrate 100 adjacent to the memory gate structure MG, and a drain region 190d may be formed in the semiconductor substrate 100 adjacent to the select gate structure SG. The formation of the source region 190s and the drain region 190d may include performing an ion implantation process using the memory gate structure MG and the select gate structure SG as masks.

As discussed above, a conductive pattern having a tip-shaped, first protrusion may be formed. Consequently, a tunnel insulator may not need to be formed so as to be in contact with a semiconductor substrate and a floating junction region, thus making cell shrinkage possible. In addition, a programming and an erasing operation may be conducted using the tip-shaped, first protrusion to enhance programming and erasing efficiency. Accordingly, it may be possible to reduce cell size while enhancing operation characteristics of a non-volatile memory device.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A non-volatile memory device comprising:
a conductive pattern on a semiconductor substrate;
a tunnel insulator on the conductive pattern;
a memory gate structure covering a first end of the conductive pattern; and
a select gate structure covering a second end of the conductive pattern.

2. The non-volatile memory device of claim 1, wherein the conductive pattern includes
a base portion contacting the semiconductor substrate, the base portion between the first and second ends of the conductive pattern; and
a first protrusion at the first end, the first protrusion tapering upwards.

3. The non-volatile memory device of claim 2, wherein the conductive pattern includes a second protrusion at the second end, the second protrusion tapering upwards and substantially symmetrical to the first protrusion.

4. The non-volatile memory device of claim 3, wherein the first and second protrusions include
an outer side surface that is substantially perpendicular to a bottom surface of the base portion; and
an inner side surface that is convex.

5. The non-volatile memory device of claim 3, wherein the coverage of the first protrusion by the memory gate structure is greater than the coverage of the second protrusion by the select gate structure.

6. The non-volatile memory device of claim 1, wherein
the memory gate structure includes a gate insulator, a floating gate, an intergate dielectric, and a sensing gate sequentially stacked on the semiconductor substrate, the floating gate covering a first protrusion at the first end of the conductive pattern; and
the select gate structure includes a gate insulator, a first select gate, an intergate dielectric, and a second select gate sequentially stacked on the semiconductor substrate.

7. The non-volatile memory device of claim 6, wherein
a programming operation includes storing charges to the floating gate from the first protrusion, and
an erasing operation includes ejecting charges to the first protrusion from the floating gate.

8. The non-volatile memory device of claim 6, wherein the tunnel insulator is thinner than the gate insulator.

9. The non-volatile memory device of claim 6, wherein the tunnel insulator and the gate insulator are made of at least one of a thermal oxide and a middle-temperature oxide.

10. The non-volatile memory device of claim 1, wherein the conductive pattern includes a polysilicon doped with impurities.

11. The non-volatile memory device of claim 1, further comprising:
a floating impurity region in the semiconductor substrate, wherein the floating impurity region contacts the conductive pattern.

12. The non-volatile memory device of claim 1, further comprising:
a source region in the semiconductor substrate adjacent to the memory gate structure; and
a drain region in the semiconductor substrate adjacent to the select gate structure.

13. A method of forming a non-volatile memory device, comprising:
forming a conductive pattern on a semiconductor substrate, the conductive pattern having a first end and a second end, a base portion between the first and second ends, a first protrusion at the first end, and a second protrusion at the second end;
forming a tunnel insulator on the conductive pattern;
forming a memory gate structure on the first protrusion; and
forming a select gate structure on the second protrusion.

14. The method of claim 13, wherein the first and second protrusions include
an outer side surface that is substantially perpendicular to a bottom surface of the base portion; and
an inner side surface that is convex.

15. The method of claim 13, wherein the conductive pattern is formed of polysilicon doped with impurities.

16. The method of claim 13, wherein forming the conductive pattern includes
forming a mask pattern on a semiconductor substrate, the mask pattern having an opening;
forming a conductive layer in the opening;
anisotropically etching the conductive layer such that the conductive layer on an upper sidewall of the opening is tapered;
planarizing the conductive layer so as to remove the conductive layer on an upper surface of the mask pattern;
performing a thermal oxidation process to form a silicon oxide layer on the conductive layer in the opening; and
removing the mask pattern.

17. The method of claim 13, further comprising:
diffusing impurities into the semiconductor substrate to form a floating impurity region below the conductive pattern.

18. The method of claim 13, wherein forming the memory gate structure and the select gate structure includes
forming a gate insulator on the semiconductor substrate and a tunnel insulator on the conductive pattern;
forming a first gate layer on the gate insulator and the tunnel insulator;
forming an intergate dielectric on the first gate layer;
forming a second gate layer on the intergate dielectric; and
etching the second gate layer, the intergate dielectric, and the first gate layer to expose a top surface of the base portion of the conductive pattern.

19. The method of claim 18, wherein the gate insulator and tunnel insulator are simultaneously formed.

20. The method of claim 18, wherein forming the gate insulator and the tunnel insulator includes performing a chemical vapor deposition process to form a middle-temperature oxide.

21. The method of claim 18, wherein forming the gate insulator and the tunnel insulator includes thermally oxidizing the conductive pattern and the semiconductor substrate to form a thermal oxide layer.

22. The method of claim 21, wherein forming the gate insulator and the tunnel insulator includes forming a middle-temperature oxide on the thermal oxide layer.

23. The method of claim 13, further comprising:
forming a source region in the semiconductor substrate adjacent to the memory gate structure; and
forming a drain region in the semiconductor substrate adjacent to the select gate structure.

24. The method of claim 13, wherein
the memory gate structure and the select gate structure are simultaneously formed, and
the coverage of the first protrusion by the memory gate structure is greater than the coverage of the second protrusion by the select gate structure.
